(19) United States
(12) Patent Application Publication
(10) Pub. No.: US 2024/0310726 A1
(43) Pub. Date: Sep. 19, 2024

(54) PHOTORESIST PROCESS

(71) Applicant: HELIO DISPLAY MATERIALS LIMITED, Oxford (GB)

(72) Inventors: Gerardus Keyzer DE KEYZER, Oxford (GB); Nobuya SAKAI, Oxford (GB); Bernard WENGER, Oxford (GB)

(21) Appl. No.: 18/575,583

(22) PCT Filed: Jun. 30, 2022
(86) PCT No.: PCT/EP2022/068183

§ 371 Date: Dec. 29, 2023

(30) Foreign Application Priority Data
Jul. 1, 2021 (GB) 2109566.6

(51) Int. Cl. G03F 7/004; C09K 11/02; C09K 11/06; G02B 5/20; G03F 7/00; G03F 7/029; G03F 7/031; G03F 7/033; G03F 7/038; G03F 7/20

(52) U.S. Cl. CPC G03F 7/0047; C09K 11/02; C09K 11/06; G02B 5/206; G03F 7/0007; G03F 7/0035; G03F 7/029; G03F 7/031; G03F 7/033; G03F 7/0384; G03F 7/2002

(57) ABSTRACT

The present invention relates to a process for producing a patterned film comprising particles comprising an AMX compound, which process comprises: (a) providing a photoresist layer disposed on a substrate, which photoresist layer comprises a mixture of a photoresist and particles comprising an AMX compound; (b) defining a pattern on the photoresist layer by exposing regions of the photoresist layer to light and thereby producing a patterned photoresist layer; and (c) treating the patterned photoresist layer with a developer to produce the patterned film comprising particles comprising an AMX compound. The developer may comprise a solvent which has a dielectric constant of at least 6.0. The invention also relates to a process for producing a patterned colour conversion layer and a process for producing a device (such as a display). Further related to the invention is a device intermediate.

### FIELD OF THE INVENTION

The invention relates to a photoresist process. Processes for producing a patterned film comprising particles of an AMX compound are described. Also described are processes for producing colour conversion layers for display applications.

### BACKGROUND OF THE INVENTION

The large majority of colour displays use an additive three-channel system, such as the RGB colour model to display colours. In this model, red (R), green (G) and blue (B) emission is combined from discrete pixels to represent colour images. Current and emerging displays technologies use different methods to generate the RGB channels. For example, in mainstream liquid crystal displays (LCD), a white backlight is generated behind the liquid crystal panel and then filtered by narrowband colour filters to let the desired colours be emitted from the surface of the display. Due to their efficiency, stability and narrowband emission, blue GaN-based inorganic LEDs are usually used as primary light sources to generate the white backlight via colour conversion, or down-conversion. Typically, phosphors are placed on top of the LED semiconductor die and convert a fraction of the blue light into yellow light by absorbing the incident blue photons and re-emitting photons at a lower energy (longer wavelength). The quality of the white light generated by this process, as well as its efficiency, depends strongly on the phosphors.

The colour space that can be represented by a given emissive display is known as the colour gamut. A wide colour gamut is desired to display vivid and lifelike images. In the RGB colour model, a wide gamut can be achieved when the RGB pixels produce highly saturated colours characterised by their narrow emission spectra.

In order to generate bright and colourful displays, various down-converters can be used. Traditional inorganic phosphors (e.g. YAG or nitride phosphors) are usually efficient but suffer from broadband emission spectra, reducing the colour gamut, and low light absorption coefficients. Therefore, alternative emitters such as semiconductor quantum dots have recently been used in some high-end displays to improve the colour gamut. Quantum dots are usually made of nano-sized InP or CdSe cores surrounded by wider bandgap semiconductor shells. When synthesized with narrow size distribution within the range 2-10 nm, quantum dots can emit light with narrow spectra (full width at half maximum, FWHM, of 20-40 nm) allowing for high colour saturation.

More recently, AMX compounds such as metal halide perovskites have been shown to be capable of excellent saturation properties, with FWHM similar or even narrower than quantum dots. In contrast with quantum dots, the emission wavelength of perovskites is mostly defined by their composition and not their size. For example, a green perovskite such as CsPbBr₃ has a bulk bandgap around 2.3 eV, consistent with light emission in the green wavelength range (510-540 nm). In comparison, InP and CdSe have bulk bandgaps in the NIR range (1.34 eV and 1.74 eV, respectively) and require quantum confinement to emit in the visible range. Combined with their high photoluminescence quantum efficiency (PLQY), perovskites are therefore excellent materials for colour conversion.

A desired colour-conversion architecture for displays is the “in-pixel” conversion layout, where the down-conversion material is deposited as a patterned array on top of the light-switching element. The light-switching element can be for example, a liquid crystal cell (in an LCD display), a blue mini- or μLED, or a blue OLED. A preferred manufacturing method for producing a patterned array is the use of photoresists containing the colour converting materials (Choi et al, pp39-57, in “Flat Panel Display Manufacturing”, Wiley & Sons (Ed.), 2018, DOI: 10.1002/9781119161387). Such photoresists are widely used for manufacturing colour filter arrays used in flat panel displays. They provide cost-effective and scalable methods to pattern arrays with high resolution and accuracy. Therefore, they are preferred to less reliable methods such as ink-jet printing.

However, metal halide perovskites being ionic compounds, unlike colour pigments or quantum dots, are considered to be unsuitable for photoresist formulations and the development process, which typically involves aqueous developer solution. The standard colour-filter photolithography processes use basic aqueous developer solutions. Examples are KOH or TMAH (tetramethylammonium hydroxide) aqueous solutions. Due to their ionic nature, metal halide perovskites are expected to be damaged during this process with degradation occurring in an aqueous environment (Kim et al, Angew. Chem. Int. Ed. 2020, 59, 10802-10806; Loiudice et al, Angew. Chem. Int. Ed. 2017, 56, 10696-10701).

Alternative methods have therefore been proposed for producing patterned arrays of perovskite particles. For instance, CN108987613A discloses a method to pattern perovskite colour-conversion materials without mixing with a photoresist.

Patterning of perovskite light emitters has been demonstrated using various techniques, including photolithography, which have been reviewed in Jeong, B et al, Adv. Mater., 2020, 32, 2000597. A preferred method for display applications is ink-jet printing, but despite its promise of high efficiency and low material usage it has not yet used in large scale flat panel display manufacturing, which is mainly due to low production yields. Other patterning methods used for perovskites include top-down approaches such as focussed ion beam etching, E-beam lithography and reactive ion etching. Photolithography has been used in indirect ways, where the photoresist acts as a protecting layer for reactive etching or using lift-off processes. Other techniques such as laser ablation, nanoimprinting and self-assembly have also been demonstrated.

Another approach to prepare patterned films for colour conversion using perovskites, consists in mixing precursors with a resin formulation and synthesizing the perovskites in situ upon exposure to light (Tan, J H et al., Adv. Mater. Technol. 2020, DOI: 10.1002/admt.202000104), or by heating to remove the solvent (CN108987613A).

Size-exclusion photolithography, where perovskite nanocrystals migrate to non-exposed regions as the film is shrinking by cross-linking in the exposed regions, has also been described for perovskites (Minh, D N et al, Adv. Mater., 2018, DOI: 10.1002/adma.201802555).

There is a need to develop a convenient and scalable method for producing patterned films comprising particles of AMX compounds which can in turn be used to produce patterned colour conversion layers.

### SUMMARY OF THE INVENTION

The inventors have unexpectedly found that a photoresist process can be conducted using particles of an AMX compound to produce a patterned film comprising the particles, without unacceptable degradation of the AMX compound taking place.

The invention accordingly provides a process for producing a patterned film comprising particles comprising an AMX compound, which process comprises: (a) providing a photoresist layer disposed on a substrate, which photoresist layer comprises a mixture of a photoresist and particles comprising an AMX compound; (b) defining a pattern on the photoresist layer by exposing regions of the photoresist layer to light and thereby producing a patterned photoresist layer; and (c) treating the patterned photoresist layer with a developer to produce the patterned film comprising particles comprising an AMX compound.

It has been found that the photoresist process may be conducted successfully using particles of an AMX compound even when preferred polar developers such as aqueous hydroxide are used. These developers had been thought likely to cause degradation of the AMX compound.

The invention further provides a process for producing a patterned film comprising particles comprising an AMX compound, which process comprises: (a) providing a photoresist layer disposed on a substrate, which photoresist layer comprises a mixture of a photoresist and particles comprising an AMX compound; (b) defining a pattern on the photoresist layer by exposing regions of the photoresist layer to light and thereby producing a patterned photoresist layer; and (c) treating the patterned photoresist layer with a developer to produce the patterned film comprising particles comprising an AMX compound, wherein: the developer comprises a solvent, which solvent has a dielectric constant of at least 6.0; and the AMX compound comprises a compound of Formula (I):

[A]ₐ[M]_{b}[X]_{c} (I)

wherein: [A] comprises one or more monocations; [M] comprises one or more metal or metalloid cations; [X] comprises one or more halide anions; a is from 1 to 8; b is from 1 to 4; and c is from 3 to 10.

Also provided by the invention is a process for producing a patterned film comprising particles comprising an AMX compound, which process comprises treating a patterned photoresist layer with a developer to produce the patterned film comprising particles comprising an AMX compound, wherein: the patterned photoresist layer comprises (a) regions comprising a cured photoresist and particles comprising an AMX compound and (b) regions comprising an uncured photoresist and particles comprising an AMX compound; and the developer comprises a solvent. The solvent typically has a dielectric constant of at least 6.0. The AMX compound typically comprises a compound of Formula (I):

[A]ₐ[M]_{b}[X]_{c} (I)

wherein: [A] comprises one or more monocations; [M] comprises one or more metal or metalloid cations; [X] comprises one or more halide anions; a is from 1 to 8; b is from 1 to 4; and c is from 3 to 10.

The invention also provides a device intermediate comprising (i) a patterned photoresist layer disposed on a substrate and (ii) a developer, wherein: the patterned photoresist layer comprises (a) regions comprising a cured photoresist and particles comprising an AMX compound and (b) regions comprising an uncured photoresist and particles comprising an AMX compound; and the developer comprises a solvent. The solvent typically has a dielectric constant of at least 6.0. The AMX compound typically comprises a compound of Formula (I):

[A]ₐ[M]_{b}[X]_{c} (I)

wherein: [A] comprises one or more monocations; [M] comprises one or more metal or metalloid cations; [X] comprises one or more halide anions; a is from 1 to 8; b is from 1 to 4; and c is from 3 to 10.

Further provided by the invention is a photoresist mixture comprising a photoresist and particles comprising an AMX compound.

### BRIEF DESCRIPTION OF THE FIGURES

FIG. 1 shows optical micrographs of the green (left) and red (right) patterned perovskite films of Example 1.

FIG. 2 shows photoluminescence spectra of green (left) and red (right) perovskite films of Example 1, before and after the development and baking steps.

FIG. 3 shows an optical micrograph of the green patterned perovskite film of Example 2.

FIG. 4 shows photoluminescence spectra of green perovskite films of Example 2, before and after the development and baking steps.

FIG. 5 shows a photoluminescence image of a patterned film as obtained by Example 3.

FIG. 6 shows the photoluminescence spectrum of a patterned film before and after development as obtained by Example 3.

### DETAILED DESCRIPTION OF THE INVENTION

### Definitions

The term “perovskite”, as used herein, refers to a material with a crystal structure related to that of CaTiO₃ or a material comprising a layer of material, which layer has a structure related to that of CaTiO₃. The structure of CaTiO₃ can be represented by the formula AMX₃, wherein A and M are cations of different sizes and X is an anion. In the unit cell, the A cations are at (0,0,0), the M cations are at (1/2, 1/2, 1/2) and the X anions are at (1/2, 1/2, 0). The A cation is usually larger than the M cation. The skilled person will appreciate that when A, M and X are varied, the different ion sizes may cause the structure of the perovskite material to distort away from the structure adopted by CaTiO₃ to a lower-symmetry distorted structure. The symmetry will also be lower if the material comprises a layer that has a structure related to that of CaTiO₃. Materials comprising a layer of perovskite material are well known. For instance, the structure of materials adopting the K₂NiF₄-type structure comprises a layer of perovskite material. The skilled person will appreciate that a perovskite material can be represented by the formula [A][M][X]₃, wherein [A] is at least one cation, [M] is at least one cation and [X] is at least one anion. When the perovskite comprise more than one ion (for instance more than one A cations), the different ions may distributed over the ion sites in an ordered or disordered way. The symmetry of a perovskite comprising more than one A cation, more than one M cation or more than one X cation, will be lower than that of CaTiO₃.

The term “metal halide perovskite”, as used herein, refers to a perovskite, the formula of which contains at least one metal cation and at least one halide anion. The term “organic-inorganic metal halide perovskite”, as used herein, refers to a metal halide perovskite, the formula of which contains at least one organic cation.

The term “hexahalometallate”, as used herein, refers to a compound which comprises an anion of the formula [MX₆]ⁿ⁻ wherein M is a metal atom, each X is independently a halide anion and n is an integer from 1 to 4.

The term “chalcogenide” refers to an anion of the elements of group 16, for instance O₂₋, S₂₋, S2₂₋, or Te²⁻. Typically, the chalcogenides are taken to be S₂₋, S2₂₋, and Te²⁻.

The term “monocation”, as used herein, refers to any cation with a single positive charge, i.e. a cation of formula A⁺ where A is any moiety, for instance a metal atom or an organic moiety. The term “dication”, as used herein, refers to any cation with a double positive charge, i.e. a cation of formula A²⁺ where A is any moiety, for instance a metal atom or an organic moiety. The term “tetracation”, as used herein, refers to any cation with a quadruple positive charge, i.e. a cation of formula A⁴⁺ where A is any moiety, for instance a metal atom.

The term “organic group”, as used herein, refers to a chemical moiety comprising carbon and hydrogen atoms. The organic group optionally further comprises oxygen or nitrogen atoms. An organic group may for instance be a substituted or unsubstituted alkyl group or a substituted or unsubstituted aryl group.

The term “alkyl”, as used herein, refers to a linear or branched chain saturated hydrocarbon radical. An alkyl group may be a C₁₋₂₀ alkyl group, a C₁₋₁₄ alkyl group, a C₁₋₁₀ alkyl group, a C₁₋₆ alkyl group or a C₁₋₄ alkyl group. Examples of a C₁₋₁₀ alkyl group are methyl, ethyl, propyl, butyl, pentyl, hexyl, heptyl, octyl, nonyl or decyl. Examples of C₁₋₆ alkyl groups are methyl, ethyl, propyl, butyl, pentyl or hexyl. Examples of C₁₋₄ alkyl groups are methyl, ethyl, i-propyl, n-propyl, t-butyl, s-butyl or n-butyl. If the term “alkyl” is used without a prefix specifying the number of carbons anywhere herein, it has from 1 to 6 carbons (and this also applies to any other organic group referred to herein). An alkyl group is typically unsubstituted.

The term “aryl”, as used herein, refers to a monocyclic, bicyclic or polycyclic aromatic ring which contains from 6 to 14 carbon atoms, typically from 6 to 10 carbon atoms, in the ring portion. Examples include phenyl, naphthyl, indenyl, indanyl, anthracenyl and pyrenyl groups. Typically an aryl group is a phenyl group.

The term “substituted”, as used herein in the context of substituted organic groups, refers to an organic group which bears one or more substituents selected from C₁₋₁₀ alkyl, aryl (as defined herein), cyano, amino, nitro, C₁₋₁₀ alkylamino, di(C₁₋₁₀)alkylamino, arylamino, diarylamino, aryl(C₁₋₁₀)alkylamino, amido, acylamido, hydroxy, oxo, halo, carboxy, ester, acyl, acyloxy, C₁₋₁₀ alkoxy, aryloxy, halo(C₁₋₁₀)alkyl, sulfonic acid, thiol, C₁₋₁₀ alkylthio, arylthio, sulfonyl, phosphoric acid, phosphate ester, phosphonic acid and phosphonate ester. Examples of substituted alkyl groups include haloalkyl, perhaloalkyl, hydroxyalkyl, aminoalkyl, alkoxyalkyl and alkaryl groups. When a group is substituted, it may bear 1, 2 or 3 substituents. For instance, a substituted group may have 1 or 2 substituents.

The term “dispose” as used here in means to place, or make available, a material at a particular location. For instance, disposing a material on a substrate may comprise depositing a material on a substrate.

### Process for Producing a Patterned Film

The process is a process for producing a patterned film comprising particles comprising an AMX compound. The patterned film may also be referred to as a patterned layer. The patterned film is typically disposed on a substrate. The patterned film typically comprises a plurality of regions of a matrix material comprising the particles. For instance, the patterned film may comprise a plurality of regions of a matrix material comprising the particles, which regions are disposed on a substrate. The patterned film may comprise a single continuous region of a matrix material comprising the particles, which single continuous region forms a pattern (for instance a comb-like pattern). The patterned film may comprise a plurality of discontinuous regions of a matrix material comprising the particles, which plurality of discontinuous regions forms a pattern (for instance a plurality of dots or pixels). The pattern may be a repeating pattern (e.g. a pattern with translational symmetry) or the pattern may be a non-repeating pattern, for instance an arrangement of the regions of the matrix material comprising the particles which arrangement forms an image.

The patterned film comprising particles comprising an AMX compound is typically a patterned film with particles comprising an AMX compound dispersed therein. As such, the particles comprising an AMX compound are typically dispersed within the matrix material. The matrix material in which the particles is dispersed is typically a matrix material formed by curing of the photoresist. The matrix material is typically a polymer. The matrix material is typically transparent. For instance, the matrix material may have a total light transmittance of at least 70% or at least 80%.

The particles may be dispersed within the patterned film in an ordered or disordered way. Typically, the particles are dispersed within the patterned film in a disordered way. For instance, while the patterned film may comprise an ordered array of regions of a matrix material comprising the particles (such as an array of pixels comprising the matrix material comprising particles), the distribution of the particles within each region of the matrix material is not necessarily ordered. The particles may be dispersed in a random and substantially uniform way within the matrix material forming the patterned film.

The pattern defined on the photoresist layer may be an array of pixels. As such, the patterned film comprising particles of an AMX compound may comprise an array of pixels of a matrix material with the particles of an AMX compound dispersed in the matrix material. An array of pixels is typically a regular arrangement of regions of a matrix material which may be used to form a display. The array of pixels may form a regular two-dimensional grid. Each pixel may for instance have a substantially rectangular shape or a substantially circular shape when viewed in a direction perpendicular to the substrate. The area of each pixel may for instance be from 1.0 μm² to 1.0 mm². The array of pixels may form part of an RGB colour conversion layer. The array of pixels may have a pixel density of from 10 to 1000 pixels per inch (ppi), for instance from 100 to 800 ppi.

Step (a) comprises providing a photoresist layer disposed on a substrate. The substrate may be any suitable substrate. The substrate may for instance comprise a layer of glass or a layer of a polymer. The substrate is typically transparent. For instance, the substrate may have a total light transmittance of at least 70% or at least 80%.

The substrate may already additionally comprise a (first) patterned film comprising particles comprising an AMX compound (for instance a different AMX compound from the AMX compound in the particles in the photoresist layer). This may be the case if the process of the invention is being carried out as part of a second or subsequent step in the production of a colour conversion layer comprising a plurality of patterned films comprising particles of an AMX compound. The substrate may alternatively or additional comprise further layers. For example, the substrate may comprise (i) a first layer comprising glass or a polymer and (ii) a second layer comprising an optical adhesive, an overcoat and/or a patterned film comprising particles comprising an AMX compound. The photoresist layer is typically in contact with the second layer of the substrate.

The process may further comprise a step of producing the photoresist layer disposed on a substrate, the step comprising depositing a mixture of a photoresist and particles comprising an AMX compound on the substrate. The mixture of the photoresist and the particles may be deposited on the substrate by blade coating, spin coating, slit coating or slot-die coating. The mixture of a photoresist and particles comprising an AMX compound may additional comprise a solvent (for instance toluene or xylene). The solvent may be allowed to evaporate after the photoresist, particles comprising an AMX compound and solvent have been disposed on a substrate.

The photoresist layer comprises a mixture of a photoresist and the particles comprising the AMX compound. As such, the particles and the photoresist are typically directly intermixed with the photoresist in contact with the particles comprising the AMX compound.

The photoresist layer can be any suitable thickness. Typically, the photoresist layer has a thickness of from 50 nm to 1 mm, for instance from 500 nm to 500 μm. The photoresist layer may have a thickness of from 1 μm to 50 μm, for instance from 2 μm to 10 μm. After exposure to light and development, the thickness of the photoresist may be reduced. The thickness of the patterned film comprising particles comprising an AMX compound on the substrate (e.g. the maximum thickness of the patterned film in a direction perpendicular to the substrate) may be from 500 nm to 50 μm, for instance from 1 μm to 10 μm.

Step (b) comprises defining a pattern on the photoresist layer by exposing regions of the photoresist layer to light and thereby producing a patterned photoresist layer. The photoresist is photosensitive and as such by exposing regions of the photoresist to light (for instance UV light) a pattern is defined on the photoresist layer. The pattern is defined initially by chemical changes in the regions of the photoresist. The patterned photoresist layer comprises first regions of the photoresist which are at least partially cured and second regions of the photoresist which are uncured (or which are cured to a lesser extent that the first regions of the photoresist). The patterned film is then produced in a subsequent step by removal of portions of the photoresist layer using a developer (which may be the exposed or unexposed regions of the photoresist layer depending on whether the photoresist is a positive photoresist or a negative photoresist).

The patterned photoresist layer is treated with a developer to produce the patterned film. Treating the patterned photoresist layer with the developer typically comprises exposing the patterned photoresist layer to the developer. For instance, the developer may be sprayed onto the patterned photoresist layer, the developer may be coated onto the patterned photoresist layer or the patterned photoresist layer may be dipped in the developer. Typically, the developer is sprayed onto the patterned photoresist layer.

The patterned photoresist layer may be treated with the developer for any suitable length of time, for instance a length of time suitable for dissolving those regions of the photoresist layer which are to be removed by the developer. The patterned photoresist layer may be treated (contacted) with the developer for from 1 second to 5 minutes, for instance from 10 seconds to 60 seconds. The process may further comprise a step of rinsing the patterned photoresist layer after treatment with the developer, for example a step of rinsing with water or an alcohol (e.g. isopropanol). The patterned photoresist layer may be treated with the developer until substantially all of the regions of the photoresist mixture to be removed by the developer (i.e. the uncured regions) have been removed.

The developer comprises a solvent, which solvent has a dielectric constant of at least 6.0. As such, the developer comprises a relatively polar solvent. The developer may comprise one or more solvents, each of which solvents have a dielectric constant of at least 6.0. The developer may comprise at least 20 wt % of the one or more solvents having a dielectric constant of at least 6.0. The solvent or solvents may have a dielectric constant of at least 10.0, at least 20.0 or at least 30.0. For instance the solvent or solvents may have a dielectric constant of from 20.0 to 100.0. The dielectric constant of the solvent(s) is typically as measured at 20° C.

The developer may comprise one or more of water, an alcohol solvent, an ester solvent, a ketone solvent, an ether solvent, a nitrile solvent, a sulfoxide solvent or an amide solvent. The developer typically comprises water, an alcohol solvent, an ester solvent or a ketone solvent. The developer may comprise a solvent, which solvent is water.

The alcohol solvent may at least one of n-butanol, iso-butanol, n-propanol, iso-propanol, ethanol, methanol, 2-methoxyethanol and benzyl alcohol. The ester solvent may be at least one of ethyl acetate, methyl acetate and 2-methoxyethyl acetate. The ketone solvent may be at least one of acetone and methyl ethyl ketone.

The developer comprising one or more solvents having dielectric constants of at least 6.0 may additionally comprise one or more non-polar solvents. For instance, the developer may additionally comprise a hydrocarbon solvent or a chlorohydrocarbon solvent. The hydrocarbon solvent comprises only carbon and hydrogen atoms. Examples of hydrocarbon solvents include a C₅₋₁₀ alkane solvent, a C₅₋₈ cycloalkane solvent and an arene solvent (e.g. benzene, toluene, xylene). The chlorohydrocarbon solvent comprises only chlorine, carbon and hydrogen atoms. Examples of chlorohydrocarbon solvents include dichloromethane, chloroform and chloroarene solvents (e.g. chlorobenzene or dichlorobenzene).

The developer may comprise xylene and 2-methoxyethyl acetate. The developer may for instance comprise xylene (70-90 wt %) and 2-methoxyethyl acetate (20-30 wt %). 2-methoxyethyl acetate has a dielectric constant of 8.25 at 20° C.

Typically, the developer is an aqueous developer. The developer may comprise at least 50% water or at least 80 wt % water. The aqueous developer may also comprise a dissolved compound, for instance a basic compound such as a hydroxide compound. The developer may for instance be an aqueous solution of a hydroxide compound. The concentration of the hydroxide compound may be from 0.01 to 5.0 wt % relative to the total concentration of the developer. The hydroxide compound is a compound comprising hydroxide (-OH). The hydroxide compound may be potassium hydroxide, sodium hydroxide, lithium hydroxide, ammonium hydroxide, tetramethylammonium hydroxide (TMAH) or tetrabutylammonium hydroxide (TBAH). The developer may for instance be an aqueous solution of potassium hydroxide.

The developer may be an aqueous solution comprising a hydroxide compound (for instance potassium hydroxide) at a concentration of 0.047 to 0.053 wt %. The developer may be an aqueous solution comprising potassium hydroxide at a concentration of 0.050 wt %.

The developer may be an aqueous solution comprising TMAH or TBAH. The developer may be an aqueous solution comprising TMAH or TBAH at a concentration of from 0.1 to 3 wt %, for instance from 0.3 to 2.5 wt % or from 0.25 to 0.75 wt %. For instance, the developer may be an aqueous solution of TMAH at a concentration of 0.4 to 0.6 wt %.

The developer may alternatively be an aqueous solution of a carbonate compound and/or a hydrogen carbonate compound. The developer may be an aqueous solution of a carbonate buffer, for instance a sodium carbonate buffer (Na₂CO₃/NaHCO₃). The developer may be an aqueous solution of potassium carbonate.

Alternatively, the developer may be a non-polar developer. For instance, the developer may comprise one or more solvents which solvents each have a dielectric constant of no greater than 6.0 or no greater than 4.0. The developer may comprise no greater than 5 wt % of a solvent having a dielectric constant of greater than 6.0. The non-polar developer may for instance comprise one or more of a C₅₋₁₀ alkane solvent, a C₅₋₈ cycloalkane solvent, an arene solvent (e.g. benzene, toluene, xylene), dichloromethane, chloroform and a chloroarene solvent (e.g. chlorobenzene or dichlorobenzene).

The developer may contain additional components in addition to the one or more solvents. For instance, the developer may comprise a surfactant or solubilising agent.

Defining a pattern on the photoresist layer by exposing regions of the photoresist layer to light typically comprises exposing the photoresist layer to UV light through a patterned mask. The patterned mask may for instance comprise a series of transparent regions which allow light through to define a pattern on the photoresist layer. Defining a pattern on the photoresist layer may alternatively comprise projecting a pattern of light onto the photoresist layer or moving a light-source (for instance a laser) over the surface of the photoresist layer (i.e. maskless lithography).

The process typically comprises exposing regions of the photoresist to UV light having a wavelength of from 190 nm to 500 nm. Preferably, the UV light has a wavelength of 350 nm to 450 nm, for instance from 355 nm to 375 nm. The UV light may be i-line UV light (wavelength of 365 nm). The UV light exposure may be done using an LED i-line UV curing chamber.

Exposing regions of the photoresist layer to light typically comprises exposing regions of the photoresist layer to UV light at a dose of at least 40 mJ/cm² or at least 300 mJ/cm². The UV light is preferably used at a dose of from 500 to 10,000 mJ/cm², for instance from 800 to 8,000 mJ/cm². For instance, the regions of the photoresist layer may be exposed to UV light at a dose of from 1,000 to 2,000 mJ/cm² or from 5,000 to 7,000 mJ/cm².

Perovskites can have high absorption coefficients above their bandgap, which can rise up to more than 100,000 cm⁻¹ in the UV range. A significant fraction of the light required for the generation of radicals by the photoinitiators will therefore be absorbed by the perovskites themselves. However, due to the good light fastness of the perovskites, this can be overcome with relatively large UV doses.

### Photoresist

The photoresist is a light-sensitive material which can be patterned by exposure to light to form regions comprising a solid material (i.e. a matrix material). As such, the photoresist is typically able to form a matrix material within which the particles comprising the AMX compound may be dispersed. Exposure to light typically causes changes in the chemical structure of the photoresist which increases or decreases its solubility, for instance in a developer. For example, after exposure to light, some regions of the photoresist may be insoluble in a developer and accordingly remain on the substrate whereas the other regions of the photoresist may be soluble in the developer and be removed from the substrate upon treatment with the developer.

The photoresist may be a negative photoresist in which the regions of photoresist exposed to light cure, harden or have decreased solubility and remain after the light-patterned photoresist is treated with a developer. The photoresist may alternatively be a positive photoresist in which the regions of photoresist exposed to light have increased solubility and are removed when the light-patterned photoresist is treated with a developer. Typically the photoresist is a negative photoresist.

The photoresist is typically a photopolymerising resist, a photocrosslinking resist or a photodecomposing resist. The photoresist may for instance be a photopolymerising resist or a photocrosslinking resist.

A photopolymerising resist is typically a resist which comprises a monomer (which may be monofunctional or multifunctional) and a photoinitiator and which undergoes polymerisation on exposure to light. Polymerisation of the monomers cures the photoresist and reduces its solubility in the developer. As such, a photopolymerising resist is typically a negative photoresist. A photopolymerising resist typically further comprises a binder which may be an oligomer or polymer and which also reacts with the monomer during the photopolymerisation.

A photocrosslinking resist is typically a resist which comprises binder which may be an oligomer or polymer and a photoinitiator and which undergoes crosslinking on exposure to light. As such, a photocrosslinking resist is typically a negative photoresist. A photocrosslinking resist may further comprise a monomer or a cross-linking agent (which is typically a multifunctional monomer).

Some photoresists may be both photopolymerising and photocrosslinking resists, for instance if they comprise a binder, a monomer and a cross-linking agent. Such resists may undergo both polymerisation and crosslinking during light exposure.

A photodecomposing resist is typically a resist which comprises a polymer which degrades following light exposure. The polymer may break up into monomers or oligomers which are soluble in a developer, meaning that the regions of the photoresist which are exposed to light are removed on treatment with a developer. As such, a photodecomposing resist is typically a positive photoresist.

The photoresist is typically a photoradical resist in which the monomer, the cross-linking agent, and/or the prepolymer polymerise (or degrade) by a photoradical reaction in which the photoinitiator initially generates radicals on exposure to light. The photoresist may alternatively be a photocationic resist in which the monomer, the cross-linking agent, and/or the prepolymer polymerise (or degrade) by a photocationic reaction in which the photoinitiator initially generates cations on exposure to light.

The photoresist typically comprises (a) a photoinitiator and (b) one or more of a monomer, a binder and a cross-linking agent.

The photoresist may comprise (a) a photoinitiator and (b) a binder and optionally a monomer.

The photoresist may comprise (a) a photoinitiator and (b) a binder and a cross-linking agent.

The photoresist may comprise (a) a photoinitiator and (b) a binder, a monomer and a cross-linking agent.

The photoresist may comprise (a) a photoinitiator and (b) a monomer and a cross-linking agent.

The photoresist present in the photoresist layer in step (a) of the process may comprise (i) from 0 to 50 vol % of a monomer, (ii) from 0 to 20 vol % of a cross-linking agent, (iii) from 1.0 to 80 vol % of a binder, and (iv) from 0.001 to 1.0 vol % of a photoinitiator. For instance, the photoresist present in the photoresist layer may comprise (i) from 30 to 50 vol % of a monomer, (ii) from 5 to 15 vol % of a cross-linking agent, (iii) from 20 to 50 vol % of a binder, and (iv) from 0.001 to 1.0 vol % of a photoinitiator.

The photoresist optionally further comprises a solvent. The photoresist layer comprising the photoresist and the particles of the AMX compound may however already have been dried and may not comprise a significant proportion of a solvent.

### Photoinitiator

The photoresist typically comprises a photoinitiator. The photoinitiator is typically a compound which is separate from the other components in the photoresist (i.e. a different compound from the binder, monomer or cross-linking agent). The photoinitiator may alternatively be present as a moiety within the binder, monomer or cross-linking agent. For instance, the binder may comprise a moiety which acts as a photoinitiator. Preferably, however, the photoinitiator is a separate compound (i.e. it is not part of the binder, the monomer or the cross-linking agent).

The photoinitiator is a photosensitive compound that can absorb one or more photons to form a reactive species. The reactive species is typically a radical or a cation. The reactive species can initiate polymerisation, cross-linking or degradation of the other components in the photoresist. The photoinitiator may be a Norrish type I photoinitiator or a Norrish type II photoinitiator.

The photoinitiator typically comprises a compound comprising a ketone group, a compound comprising a benzoyl group, a compound comprising an azide group (—N₃), a compound comprising a phosphine oxide group, a compound comprising a phosphinate group, a compound comprising an oxime group (>C═N—O—) or a compound comprising a ketal group.

A compound comprising a benzoyl group is a compound comprising a keto group (>C═O) bonded directly to a phenyl group, which phenyl group may be substituted. A compound comprising a benzoyl group may also be known as a phenone compound.

Examples of photoinitiators include benzil ketals, hydroxyacetophenones, aminoacetophenones, phosphine oxides, benzophenones, benzyl formats and thioxanthones.

For instance, the photoinitiator may comprise:
a benzophenone photoinitiator, for instance a compound selected from benzophenone, p,p′-dichlorobenzophenone, methyl-o-benzoylbenzoate, 4,4′-bis(N,N-dimethylamino)benzophenone, 4-phenylbenzophenone, 3,3′,4,4′-tetra(t-butyl-peroxycarbonyl) benzophenone, 4- benzoyl-N-trimethylbenzene methane ammonium chloride, 2-hydroxy-3-(4-benzo-yl-phenoxy)-N,N,N-trimethyl-1-propane ammonium chloride and dibenzosuberone;
a thioxanthone photoinitiator, for instance a compound selected from thioxanthone, 2-methylthioxanthone, 2-cholorothioxanthone and 2-isopropylthioxanthone an acetophenone photoinitiator, for instance a compound selected from acetophenone, p-dimethylaminoacetophenone, 2-hydroxy-2-methyl-1-phenylpropane-1-one, 2,2-diethoxyacetophenone, 1-[4-(2-Hydroxyethoxy)phenyl]-2-hydoxy-2,2-dimethyl-1-propane-1-one, 1-hydroxy-cyclohexylphenylketone, 1-phenyl-1,2-propane dion-2-(ethoxycarboxylic)oxime, 2,2-diethoxy-1,2-diphenylethane-1-one, 2,2-dimethoxy-1,2-diphenylethane-1-one and 2-methyl-1-[4-(methylthio)phenyl]-2-morpholinepropanone;
a dicarbonyl photoinitiator, for instance a compound selected from benzil, anthroquinone, 2-ethylanthroquinone, benzoylmethylformate, 9,10-phenathrenequinone and camphorquinone; or
a benzoin ether photoinitiator, for instance a compound selected form benzoin, benzoin methyl ether, benzoin ethyl ether, benzoin isopropyl ether, benzoin tertbutyl ether, benzoin n-butyl ether.

Further photoinitiators include 2-o-chlorophenyl-4,5-bisimidazole, 2-mercaptobenzothiazole and 7-dimethylamino-4-methylcoumarine.

Preferably, the photoinitiator comprises a compound comprising a benzoyl group, a compound comprising a phosphine oxide group or a compound comprising a phosphinate group. For instance, the photoinitiator may comprise a benzophenone photoinitiator, an acetophenone photoinitiator, or a benzoin ether photoinitiator.

A phosphine oxide group is a group of formula O═PR₃, where each R is an organic group, for instance an alkyl group or an aryl group, which alkyl group or aryl group is optionally substituted. The compound comprising a phosphine oxide group may for instance be selected from bis(2,4,6-trimethylbenzoyl)phenylphosphine oxide and (2,4,6-trimethylbenzoyl)diphenylphosphine oxide.

A phosphinate group is a group of formula O═PR₂(OR), where each R is an organic group for instance an alkyl group or an aryl group, which alkyl group or aryl group is optionally substituted. The compound comprising a phosphinate group may for instance be selected from methyl(2,4,6-trimethylbenzoyl)-phenyl phosphinate and ethyl(2,4,6-trimethylbenzoyl)-phenyl phosphinate.

Preferably, the photoinitiator comprises 2-hydroxy-2-methyl-1-phenylpropanone, bis(2,4,6-trimethylbenzoyl)phenylphosphine oxide and ethyl(2,4,6-trimethylbenzoyl)-phenyl phosphinate.

The photoresist may alternatively comprise a thermally activated initiator instead of a photoinitiator. A thermally activated initiator is a compound that produces reactive species upon heating.

### Monomer

The monomer may comprise an acrylate monomer, a methacrylate monomer, an acrylamide monomer, an epoxide monomer, an alkene monomer or a phenol monomer. Typically the monomer comprises an acrylate monomer, a methacrylate monomer or an acrylamide monomer.

An acrylate monomer is a compound comprising an acrylate group, i.e. a double bond adjacent to an ester or an acid group. Typically the acrylate monomer is a compound of formula H₂C═C(H)COOR, where R is an organic group.

A methacrylate monomer is a compound comprising a methacrylate group. Typically the acrylate monomer is a compound of formula H₂C═C(CH₃)COOR, where R is an organic group.

For instance, the monomer may comprise an acrylate monomer of formula H₂C═C(H)COOR or a methacrylate monomer of formula H₂C═C(CH₃)COOR, where R is H, a C₁₋₁₀ alkyl group (for instance methyl, ethyl, n-propyl, isopropyl, n-butyl, isobutyl, t-butyl, 2-ethylhexyl, n-octyl), 2-hydroxyethyl, 2-hydroxypropyl, lauryl, cetyl, stearyl, 4-hydroxybutyl, 2-ethoxyethyl, 2-methoxyethyl, 2-methoxy-1-methylethyl, 2-phenoxyethyl, 3-methoxybutyl, ethoxydiethyleneglycol, methoxytriethyleneglycol, dimethylaminoethyl, trifluoroethyl, tetrafluoropropyl, octafluoropentyl, heptodecafluorodecyl, cylcopentyl, cylcohexyl, benzyl, phenoxyethyl, tetrahydrofurfuryl, 2-hydroxy-3-phenoxy-propyl, p-nonylphenoxyethyl, tribromophenyl, p-cresolethylene, epoxyethyl, 3-chloro-2-hydroxypropyl and dimethylaminoethyl.

An acrylamide monomer is a compound comprising an acrylamide group, i.e. a double bond adjacent to an amide group. The acrylamide monomer may be a compound of formula H₂C═C(H)CONR₂ or H₂C═C(CH₃)CONR₂ where each R is an organic group, for instance H or a C₁₋₁₀ alkyl group. The acrylamide monomer may be acrylamide, methacrylamide, N-methanol-methacrylamide or N-t-butylmethylketone methacrylamide. The monomer may comprise acrylonitrile.

An epoxide monomer is a compound comprising an epoxide group. The epoxide monomer may for instance be glycidol or epichlorohydrin.

An alkene monomer is a compound comprising a carbon-carbon double bond. An alkene monomer is typically a hydrocarbon compound comprising only carbon and hydrogen atoms. The alkene monomer may be an alkadiene, e.g. a hydrocarbon compound comprising two alkene groups such as a alka-1,4-diene. The alkene monomer may for instance be isoprene.

A phenol monomer is phenol or a substituted phenol compound. A substituted compound is typically a compound which is formed by replacing an H atom on the phenyl ring of phenol with one or more substituents. The one or more substituents may each be C₁₋₆ alkyl group. The phenol monomer may be phenol or cresol. The phenol monomer may be used in combination with a melamine cross-linker.

### Binder

The binder may comprise an acrylate binder, a methacrylate binder, an alkene binder, a vinyl binder, an epoxy binder, a urethane binder, a polyester binder, a silicone binder, a phenol binder or a novolac binder. The binder preferably comprises an acrylate binder, a methacrylate binder, an alkene binder, a vinyl binder or an epoxy binder. The binder more preferably comprises an acrylate binder, a methacrylate binder, an alkene binder (for instance an isoprene binder).

The binder (which may also be referred to as a pre-polymer) typically comprises one or more polymers and/or oligomers. The binder may comprise a polymer or oligomer having a weight average molecular weight of from 500 to 100,000 g/mol, for instance from 1,000 to 50,000 g/mol.

An acrylate binder is a binder comprising one or more acrylate groups. An acrylate binder may be an acrylate polymer or an acrylate oligomer. The acrylate binder may be formed by polymerising one or more acrylate monomers, for instance by polymerising one or more acrylate monomers as defined herein. The acrylate binder may comprise poly(acrylic acid) or poly(methyl acrylate). The acrylate binder may be a co-polymer of acrylic acid and a second monomer, for instance an acrylate monomer as defined herein. For instance, the acrylate binder may comprise a co-polymer of acrylic acid and an alkyl acrylate (e.g. a C₁₋₆ alkyl acrylate). The acrylate binder may comprise a co-polymer of acrylic acid and methyl acrylate.

A methacrylate binder is a binder comprising one or more methacrylate groups. A methacrylate binder may be a methacrylate polymer or a methacrylate oligomer. The methacrylate binder may be formed by polymerising one or more methacrylate monomers, for instance by polymerising one or more methacrylate monomers as defined herein. The methacrylate binder may comprise poly(methylmethacrylate). The methacrylate binder may be a co-polymer of methacrylic acid. For instance, the acrylate binder may comprise a co-polymer of methacrylic acid and an alkyl methacrylate (e.g. a C₁₋₆ alkyl methacrylate). The methacrylate binder may comprise a co-polymer of methacrylic acid and methyl methacrylate.

The binder may comprise a co-polymer of two or more of acrylic acid, methacrylic acid, methyl acrylate, methyl methacrylate, ethyl acrylate, ethyl methacrylate, n-propyl acrylate, n-propyl methacrylate, n-butyl acrylate, n-butyl methacrylate, 2-methoxy-1-methylethyl acetate and vinyl acetate.

An alkene binder is a binder comprising one or more alkene groups (i.e. a binder comprising one or more carbon-carbon double bonds). The alkene binder is typically an isoprene polymer. An isoprene polymer is a polymer formed by polymerisation of isoprene (2-methyl-1,3-butadiene). The isoprene polymer may have a weight average molecular weight of from 10,000 to 100,000 g/mol or from 50,000 to 80,000 g/mol, preferably from 60,000 to 70,000 g/mol.

A vinyl binder is a binder comprising one or more vinyl groups. A vinyl group is a group of formula —C(H)═CH₂.

An epoxy binder is a binder formed from one or more epoxide monomers, for instance one or more epoxide monomers as defined herein. The epoxy binder may be an epoxy resin.

A urethane binder is a binder comprising one or more urethane groups. A urethane group is a carbamate group (—N(H)—C(O)—O—). The urethane binder may be a polyurethane. The binder may comprise an aliphatic urethane acrylate oligomer, for instance an aliphatic 6F urethane acrylate oligomer.

A polyester binder is a binder comprising one or more ester groups (—C(O)—O—). For instance, the polyester binder may be formed from epoxypropylacrylate and phthalic anhydride.

A silicone binder is a binder comprising one or more siloxane groups (—Si(R₂)—O—). For instance, the silicone binder may comprise methylbutyl acrylate polysiloxane.

A phenol binder is typically a binder comprising a phenolic resin (polyphenol). The phenol binder may comprise a phenolic resin formed from a substituted or unsubstituted phenol and melamine.

A novolac binder is a binder formed by reaction of a phenol and formaldehyde. The novolac resin may for instance be formed from cresol and formaldehyde. The cresol may be ortho-, meta-or para-cresol.

Examples of binders include: an acrylate of bisphenol A-diglycidylether diacrylate epoxy resin; a diamine bisphenol A-diglycidylether diallyldimaine epoxy resin; poly(ethylene-glycoldiacylate); an oligomer of polyethylene-glycol, maleic anhydride, and propyl methacrylate; a polyurethane formed from hydroxyethylphtharyl methacrylate and xylene-isocyanate; and a polyurethane formed from polyethylene glycol, 2,4-toluene diisocyanate, and ethylmethacrylate.

The binder preferably comprises an isoprene polymer, an acrylate polymer or a methacrylate polymer.

The binder may comprise a mixture of a hexaacrylate, a triacrylate and a diacrylate. For instance, the binder may comprise hexa-functional aliphatic urethane acrylate, trimethylolpropane [3 EO] triacrylate and neopentyl glycol diacrylate. The binder may optionally comprise 30 to 50 wt % of hexa-functional aliphatic urethane acrylate, 30 to 50 wt % trimethylolpropane [3 EO] triacrylate and 10 to 30 wt % neopentyl glycol diacrylate.

### Cross-Linking Agent

The cross-linking agent is typically a compound comprising two or more groups selected from acrylate groups, methacrylate groups, alkene groups or epoxide groups. The cross-linking agent is able to cross-link separate binder molecules or to cross-link separate polymer or oligomer molecules formed by photopolymerisation of monomers.

The cross-linking agent typically comprises a compound comprising two or more acrylate groups, two or more methacrylate groups, two or more alkene groups or two or more epoxide groups. The cross-linking agent may comprise from two to six acrylate groups.

The cross-linking agent may be a compound of formula X-R′-X where: each X is an acrylate group (—O—C(O)—C(H)═CH₂), a methacrylate group (—O—C(O)—C(CH₃)═CH₂), a vinyl group (—C(H)═CH₂) or an epoxy group; and R′ is a divalent organic group. For instance, R′ may be a divalent C₂₋₂₀ alkyl group optionally interrupted with from 1 to 8 oxygen atoms. A divalent C₂₋₂₀ alkyl group is a divalent group obtained by removing two hydrogen atoms from a C₂₋₂₀ alkane. A divalent C₂₋₂₀ alkyl group optionally interrupted with from 1 to 8 oxygen atoms is a divalent C₂₋₂₀ alkyl group in which 1 to 8 C—C bonds are replaced with C—O—C bonds. R′ may be a divalent organic group selected from −(CH₂)ₙ—, —(CH₂CH₂O)ₙ—CH₂CH₂— and —(CH₂CH₂CH₂O)ₙ—CH₂CH₂CH₂— where n is from 1 to 8.

Examples of the cross-linking agent include glycerol 1,3-diglycerolate diacrylate, glycerol 1,3-diglycerolate dimethacrylate, 1,6-hexanediol diacrylate, 1,6-hexanediol dimethacrylate, 1,4-butanediol diacrylate, 1,4-butanediol dimethacrylate, pentaerythritoltetraacrylate, pentaerylthritoltriacetate, bisphenol A diglycidyl ether, bisphenol a diglycidyl ether diacrylate, diethylene glycoldiacrylate, diethylene glycoldimethacrylate, tripropylene glycoldiacrylate, tripropylene glycoldimethacrylate, hexaethylene glycoldiacrylate, hexaethylene glycoldimethacrylate, 1,3-butylene glycoldimethylmethacrylate, resorcinol di(epoxypropylene methacrylate), resorcinol di(epoxypropylene acrylate), trimethylolpropane triacrylate, ethylene glycolglyceroltriacrylate, glycerolpropylene oxide triacrylate, glyceroltriepoxypropylene acrylate, trimethylolpropane triethylene oxide acrylate, ethylene glycolglyceroltrimethacrylate, glycerolpropylene oxide trimethacrylate, glyceroltriepoxypropylene methacrylate and trimethylolpropane triethylene oxide methacrylate.

Preferably, the cross-linking agent is a diacrylate compound. For instance, the cross-linking agent may be glycerol 1,3-diglycerolate diacrylate.

The photoresist may for instance comprise: polymethylmethacrylate; a diacrylate cross-linking agent (for instance triethylene glycoldimethacrylate or glycerol 1,3-diglycerolate diacrylate) and a photoinitiator.

The photoresist may for instance comprise: an acrylate binder (for instance a co-polymer of acrylic acid or methacrylic acid); and a photoinitiator.

The photoresist may for instance comprise: a hexa-functional aliphatic urethane acrylate (aliphatic 6F urethane acrylates) binder; a pentaerythritol tetraacrylate cross-linking agent; and a photoinitiator.

The photoresist may for instance comprise: polymethylmethacrylate; triethylene glycoldimethacrylate; and a photoinitiator comprising 2-o-chlorophenyl-4,5-bisimidazole, 2-mercaptobenzothiazole, and 7-dimethylamino-4-methylcoumarine.

The photoresist may for instance comprise polyisoprene and 2-methoxyethyl acetate.

The photoresist may for instance comprise: an acrylate binder (such as polymethylmethacrylate); glycerol 1,3-diglycerolate diacrylate; 2-hydroxy-2-methylpropiophenone; phenyl bis(2,4,6-trimethylbenzoyl)-phosphine oxide; and ethyl phenyl(2,4,6-trimethylbenzoyl)phosphinate.

The photoresist may for instance comprise an acrylate binder (hexa-functional aliphatic urethane acrylate, trimethylolpropane [3 EO] triacrylate, neopentyl glycol diacrylate), glycerol 1,3-diglycerolate diacrylate, 2-hydroxy-2-methylpropiophenone, phenyl bis(2,4,6-trimethylbenzoyl)-phosphine oxide and ethyl phenyl(2,4,6-trimethylbenzoyl)phosphinate.

### Particles Comprising an AMX Compound

The patterned film comprises particles comprising an AMX compound. The AMX compound is typically an ionic compound comprising one or more monocations, one or more metal or metalloid cations and one or more anions. The particles typically comprise at least 80 wt % of the AMX compound, for instance at least 95 wt % of the AMX compound relative to the total weight of the particles.

The AMX compound is typically luminescent, for instance fluorescent or phosphorescent. For instance, the AMX compound may luminesce red or green under illumination, for instance under illumination with a gallium nitride blue-light LED. Red luminescence is typically emission of light having a wavelength of from 610 to 700 nm. Green luminescence is typically emission of light having a wavelength of from 505 to 565 nm.

The AMX compound typically comprises a compound of Formula (I):

[A]ₐ[M]_{b}[X]_{c} (I)

wherein: [A] comprises one or more monocations; [M] comprises one or more metal or metalloid cations; [X] comprises one or more anions; a is from 1 to 8; b is from 1 to 4; and c is from 3 to 10.

[A] may represent one, two or more A ions. If [A] is one cation (A), [M] is two cations (M¹ and M²), and [X] is one anion (X), the AMX compound may comprise a compound of formula Aₐ(M¹, M²)_{b}X_{c}. If [A], [M] or [X] is more than one ion, those ions may be present in any proportion. For instance, Aₐ(M¹, M²)_{b}X_{c} includes all compounds of formula AₐM¹_{by}M²_{b(1-y)}X_{c} wherein y is between 0 and 1, for instance from 0.05 to 0.95. Such compounds may be referred to as mixed ion compounds.

[A] may comprise one or more cations selected from Rb⁺, Cs⁺, (NR¹R²R³R⁴)⁺, (R¹R²N═CR³R⁴)⁺, (R¹R²N—C(R⁵)=NR³R⁴)⁺ and (R¹R²N—C(NR⁵R⁶)=NR³R⁴)⁺, wherein each of R¹, R², R³, R⁴, R⁵ and R⁶ is independently H, a substituted or unsubstituted C₁₋₂₀ alkyl group or a substituted or unsubstituted aryl group. R¹, R², R³, R⁴, R⁵ and R⁶ may be independently H, a C₁₋₆ alkyl group or a phenyl group. [A] may comprise one or more organic cations selected from (CH₃NH₃)⁺, (CH₃CH₂NH₃)⁺, (CH₃CH₂CH₂NH₃)⁺, (C6H5CH₂CH₂NH₃)⁺, (N(CH₃)4)⁺, (H₂N—C(H)═NH₂)⁺ and (H₂N—C(CH₃)═NH₂)⁺. [A] may be a single cation selected from Cs⁺, (CH₃NH₃)⁺, (CH₃CH₂NH₃)⁺, (CH₃CH₂CH₂NH₃)⁺, (C6H5CH₂CH₂NH₃)⁺, (N(CH₃)4)⁺, (H₂N—C(H)═NH₂)⁺ and (H₂N—C(CH₃)═NH₂)⁺. A is often Cs⁺, (CH₃NH₃)⁺, or (H₂N—C(H)═NH₂)⁺.

[M] may comprise one or more metal or metalloid cations selected from Au⁺, Ag⁺, Hg⁺, Cu⁺, Pb²⁺, Ca²⁺, Sr²⁺, Cd²⁺, Cu²⁺, Ni²⁺, Mn²⁺, Fe²⁺, Co²⁺, Pd²⁺, Ge²⁺, Sn²⁺, Yb²⁺, Eu²⁺, Bi³⁺, Sb³⁺, In³⁺, Au³⁺, Ti⁴⁺, V⁴⁺, Mn⁴⁺, Fe⁴⁺, Co⁴⁺, Zr⁴⁺, Nb⁴⁺, Mo⁴⁺, Ru⁴⁺, Rh⁴⁺, Pd⁴⁺, Hf⁴⁺, Ta⁴⁺, W⁴⁺, Re⁴⁺, Os⁴⁺, Ir⁴⁺, Pt⁴⁺, Sn⁴⁺, Pb⁴⁺, Po⁴⁺, Si⁴⁺, Ge⁴⁺, and Te⁴⁺.

[X] may comprise one or more anions selected from halide anions (e.g. Cl—, Br, I—) and chalcogenide anions (i.e. O²⁻, S²⁻ or Se²⁻). [X] typically comprises one or more halide anions.

Typically, [A] comprises one or more cations selected from (CH₃NH₃)⁺, (H₂N—C(H)═NH₂)⁺ and Cs⁺; [M] comprises one or more metals or metalloid dications selected from Pb²⁺, Sn²⁺, Cu²⁺ and Ge²⁺; and [X] comprises one or more of Cl⁻, Br⁻ and I⁻.

Typically, the AMX compound comprises a perovskite or a hexahalometallate. Preferably the crystalline material comprises a perovskite. The AMX compound often comprises a metal halide perovskite. The AMX compound often comprises an organic-inorganic metal halide perovskite.

Typically, the AMX compound comprises a compound of formula (II):

[A][M][X]₃ (II)

wherein: [A] comprises the one or more monocations; [M] comprises one or more metal or metalloid dications; and [X] comprises one or more halide anions.

Preferably, [A] comprises one or more organic monocations. [A] may alternatively comprise one or more inorganic monocations (for instance Cs⁺ or NH₄₊).

[M] may comprise one or more dications selected from Ca²⁺, Sr²⁺, Cd²⁺, Cu²⁺, Ni²⁺, Mn²⁺, Fe²⁺, Co²⁺, Pd²⁺, Ge²⁺, Sn²⁺, Pb²⁺, Yb²⁺ and Eu²⁺. Preferably, [M] comprises one or more dications selected from Pb²⁺, Ge²⁺, Sn²⁺ and Cu2+.

In one embodiment, the AMX compound comprises a perovskite compound of formula (IIa):

AM[X]_{3 (IIa)}

wherein: A is an organic cation; M is a metal dication; and [X] is one or more different halide anions. Preferably, [X] is two or more different halide anions.

The AMX compound may comprise a perovskite compound selected from APbl₃, APbBr₃, APbCl₃, APbF₃, APbBrₓI₃₋ₓ, APbBrₓCl₃₋ₓ, APbIₓBr₃₋ₓ, APbIₓCl₃₋ₓ, APbCIₓBr₃₋ₓ, APbI₃₋ₓClₓ, ASnl₃, ASnBr₃, ASnCl₃, ASnF₃, ASnBrl2, ASnBrₓl₃₋ₓ, ASnBrₓCl₃₋ₓ, ASnF₃₋ₓBrₓ, ASnlxBr₃₋ₓ, ASnlxCI₃₋ₓ, ASnF₃₋ₓIₓ, ASnClₓBr₃₋ₓ, ASnI₃₋ₓClₓ and ASnF₃₋ₓClₓ, ACul₃, ACuBr₃, ACuCl₃, ACuF₃, ACuBrl2, ACuBrₓl₃₋ₓ, ACuBrₓCl₃₋ₓ, ACuF₃₋ₓBrₓ, ACuIₓBr₃₋ₓ, ACuIₓCl₃₋ₓ, ACuF₃₋ₓIₓ, ACuCIxBr₃₋ₓ, ACul₃₋ₓClₓ, and ACuF₃₋ₓClₓ where x is from 0 to ₃, and wherein A is as defined herein. A may for instance be Cs⁺, (CH₃NH₃)⁺, (CH₃CH₂NH₃)⁺, (CH₃CH₂CH₂NH₃)⁺, (N(CH₃)4)⁺, (H₂N—C(H)═NH₂)⁺ or (H₂N-C(CH₃)═NH₂)⁺. Preferably, A is Cs⁺, (CH₃NH₃)⁺ or (H₂N—C(H)═NH₂)⁺. x may be from 0.05 to 2.96. For instance, x may be from 0.1 to 2.9, or from 0.5 to 2.5. In some cases, x is from 0.75 to 2.25, or from 1 to 2.

The AMX compound may comprise, or consist essentially of, a perovskite compound selected from CH₃NH₃PbI₃, CH₃NH₃PbBr₃, CH₃NH₃PbCI₃, CH₃NH₃PbF₃, CH₃NH₃PbBrₓI₃₋ₓ, CH₃NH₃PbBrₓCI₃₋ₓ, CH₃NH₃PblxBr₃₋ₓ, CH₃NH₃PbIₓCI₃₋ₓ, CH₃NH₃PbCIₓBr₃₋ₓ, CH₃NH₃PbI₃₋ₓCIₓ, CH₃NH₃SnI₃, CH₃NH₃SnBr₃, CH₃NH₃SnCI₃, CH₃NH₃SnF₃, CH₃NH₃SnBrl2, CH₃NH₃SnBrₓI₃₋ₓ, CH₃NH₃SnBrₓCI₃₋ₓ, CH₃NH₃SnF3-xBrₓ, CH₃NH₃SnIₓBr₃₋ₓ, CH₃NH₃SnIₓCI₃₋ₓ, CH₃NH₃SnF₃₋ₓIₓ, CH₃NH₃SnClxBr₃₋ₓ, CH₃NH₃SnI₃₋ₓCIₓ and CH₃NH₃SnF₃₋ₓCIₓ, CH₃NH₃CuI₃, CH₃NH₃CuBr₃, CH₃NH₃CuCI₃, CH₃NH₃CuF₃, CH₃NH₃CuBrl2, CH₃NH₃CuBrₓI₃₋ₓ, CH₃NH₃CuBrₓCI₃₋ₓ, CH₃NH₃CuF3-xBrₓ, CH₃NH₃CuIₓBr₃₋ₓ, CH₃NH₃CuIₓCI₃₋ₓ, CH₃NH₃CuF₃₋ₓIₓ, CH₃NH₃CuCIₓBr₃₋ₓ, CH₃NH₃CuI₃₋ₓCIₓ, CH₃NH₃CuF₃₋ₓCIₓ, (H₂N—C(H)═NH₂)PbI₃, (H₂N—C(H)═NH₂)PbBr3, (H₂N—C(H)═NH₂)PbCI₃, (H₂N—C(H)═NH₂)PbF₃, (H₂N—C(H)═NH₂)PbBrₓI₃₋ₓ, (H₂N—C(H)═NH₂)PbBrₓCI₃₋ₓ, (H₂N—C(H)═NH₂)PbIₓBr₃₋ₓ, (H₂N—C(H)═NH₂)PbIₓCI₃₋ₓ, (H₂N—C(H)═NH₂)PbCIₓBr₃₋ₓ, (H₂N—C(H)═NH₂)PbI₃₋ₓCIₓ, (H₂N—C(H)═NH₂)SnI₃, (H₂N—C(H)═NH₂)SnBr₃, (H₂N—C(H)═NH₂)SnCI₃, (H₂N—C(H)═NH₂)SnF₃, (H₂N—C(H)═NH₂)SnBrl2, (H₂N—C(H)═NH₂)SnBrₓI₃₋ₓ, (H₂N—C(H)═NH₂)SnBrₓCI₃₋ₓ, (H₂N—C(H)═NH₂)SnF₃₋ₓBrₓ, (H₂N—C(H)═NH₂)SnIₓBr₃₋ₓ, (H₂N—C(H)═NH₂)SnIₓCI₃₋ₓ, (H₂N—C(H)═NH₂)SnF₃₋ₓIₓ, (H₂N—C(H)═NH₂)SnCIxBr₃₋ₓ, (H₂N—C(H)═NH₂)SnI₃₋ₓCIₓ, (H₂N—C(H)═NH₂)SnF₃₋ₓCIₓ, (H₂N—C(H)═NH₂)CuI₃, (H₂N—C(H)═NH₂)CuBr₃, (H₂N—C(H)═NH₂)CuCI₃, (H₂N—C(H)═NH₂)CuF₃, (H₂N—C(H)═NH₂)CuBrl2, (H₂N—C(H)═NH₂)CuBrₓI₃₋ₓ, (H₂N—C(H)═NH₂)CuBrₓCI₃₋ₓ, (H₂N—C(H)═NH₂)CuF₃₋ₓBrₓ, (H₂N—C(H)═NH₂)CuIₓBr₃₋ₓ, (H₂N—C(H)═NH₂)CuIₓCI₃₋ₓ, (H₂N—C(H)═NH₂)CuF₃₋ₓIₓ, (H₂N—C(H)═NH₂)CuCIₓBr₃₋ₓ, (H₂N—C(H)═NH₂)CuI₃₋ₓCIₓ, (H₂N—C(H)═NH₂)CuF₃₋ₓCIₓ, CsPbI₃, CsPbBr₃, CsPbCI₃, CsPbF₃, CsPbBrₓI₃₋ₓ, CsPbBrₓCI₃₋ₓ, CsPbIₓBr₃₋ₓ, CsPbIₓCI₃₋ₓ, CsPbCIₓBr₃₋ₓ, CsPbI₃₋ₓCIₓ, CsSnI₃, CsSnBr₃, CsSnCI₃, CsSnF₃, CsSnBrI₂, CsSnBrₓI₃₋ₓ, CsSnBrₓCI₃₋ₓ, CsSnF₃₋ₓBrₓ, CsSnIₓBr₃₋ₓ, CsSnIₓCI₃₋ₓ, CsSnF₃₋ₓIₓ, CsSnClxBr₃₋ₓ, CsSnI₃₋ₓCIₓ, CsSnF₃₋ₓCIₓ, CsCuI₃, CsCuBr₃, CsCuCI₃, CsCuF₃, CsCuBrI₂, CsCuBrₓI₃₋ₓCsCuBrₓCI₃₋ₓ, CsCuF₃₋ₓBrₓ, CsCuIₓBr₃₋ₓ, CsCuIₓCI₃₋ₓ, CsCuF₃₋ₓIₓ, CsCuCIₓBr₃₋ₓ, CsCuI₃₋ₓCIₓ and CsCuF₃₋ₓCIₓ where x is from 0 to 3. x may be from 0.05 to 2.95. For instance, x may be from 0.1 to 2.9, or from 0.5 to 2.5. In some cases, x is from 0.75 to 2.25, or from 1 to 2.

The AMX compound may comprise a perovskite compound of formula (IIb):

[A]Pb[X]₃ (IIb)

wherein: [A] is one or more of Cs⁺, (CH₃NH₃)⁺ and (H₂N—C(H)═NH₂)+; and [X] is one or more of I⁻, Br⁻ and Cl⁻.

Preferably, the AMX compound comprises a perovskite compound which is (H₂N—C(H)═NH₂)PbBr₃, CsPb(IₓBrₓ)₃, (H₂N—C(H)═NH₂)_{y}Cs_{y}PbBr₃ or CsPbBr₃, wherein y is from 0.0 to 1.0 (for instance from 0.1 to 0.9) and x is from 0.0 to 1.0 (for instance from 0.1 to 0.9). More preferably the AMX compound comprises a perovskite compound which is (H₂N—C(H)═NH₂)PbBr₃ or CsPb(I_{0.6}Br_{0.4})₃.

In one embodiment, the AMX compound comprises a layered perovskite of formula (III):

[A]2[M][X]₄ (III)

wherein: [A] comprises at least one monocation; [M] comprises at least one metal or metalloid dication; and [X] comprises at least one halide anion. [A], [M] and [X] may be as defined for the perovskite compounds of formula (II) above.

In the compound of formula (III): [A] may comprise a monocation of formula (RNH₃)⁺where R is a C₁₋₁₀ alkyl group optionally substituted with phenyl, for instance a C₄₋₈ alkyl group or a phenylethyl group (C₆H₅CH₂CH₂—); [M] may comprise one or more of Pb²⁺, Ge²⁺, Sn²⁺ and Cu2+; and [X] may comprise I⁻, Br⁻ and Cl⁻.

The AMX compound may comprise a layered perovskite of formula Cs₂PbBr₄, (CH₃CH₂CH₂CH₂NH₃)2PbBr4 or (C₆H₅CH₂CH₂NH₃)₂PbBr₄.

The AMX compound may for instance comprise a hexahalometallate of formula (IV):

[A]2[M][X]₆ (IV)

wherein: [A] is at least one monocation; [M] is at least one metal or metalloid tetracation; and [X] is at least one halide anion. Typically, [A] comprises one or more of Cs⁺, (NR¹R²R³R⁴)⁺, (R¹R²N═CR³R⁴)⁺, (R¹R²N—C(R⁵)═NR³R⁴)⁺ and (R¹R²N—C(NR⁵R⁶)=NR³R⁴)⁺, wherein each of R¹, R², R³, R⁴, R⁵ and R⁶ is independently H, a C₁₋₂₀ alkyl group or a phenyl group. [A] may for instance comprises one or more of Cs⁺, (CH₃NH₃)⁺, (CH₃CH₂NH₃)⁺, (CH₃CH₂CH₂NH₃)⁺, (N(CH₃)4)⁺, (H₂N—C(H)═NH₂)+and (H₂N—C(CH₃)═NH₂)⁺. Typically, [M] comprises one or more of Ti⁴⁺, V⁴⁺, Mn⁴⁺, Fe⁴⁺, Co⁴⁺, Zr⁴⁺, Nb⁴⁺, Mo⁴⁺, Ru⁴⁺, Rh⁴⁺, Pd⁴⁺, Hf⁴⁺, Ta⁴⁺, W⁴⁺, Re⁴⁺, Os⁴⁺, Ir⁴⁺, Pt⁴⁺, Sn⁴⁺, Pb⁴⁺, Po⁴⁺, Si⁴⁺, Ge⁴⁺, and Te⁴⁺. Preferably, [M] comprises one or more of Sn⁴⁺ and Pb⁴⁺.

The AMX compound may comprise a hexahalometallate of formula Cs₂PbBr₆.

The AMX compound may comprise a double perovskite compound of formula (V):

[A]₂[M^{I}][M^{III}][X]₆ (V)

wherein: [A] is at least one monocation; [MI] is at least one metal or metalloid monocation; [MIII ] is at least one metal or metalloid trication; and [X] is at least one halide anion. [A] and [X] may be as defined above for the perovskite compounds. [MI] may comprise one or more of Ag⁺, In⁺, Au⁺ and Cut. [MIII] may comprise one or more of Bi³⁺, Sb³⁺, Au³⁺ and In³⁺.

The AMX compound may comprise a double perovskite of formula Cs₂AgBiBr₆.

The AMX compound may additional comprise a dopant. For instance, the AMC compound may be doped with Mn, Y, Yb or Eu.

The particles comprising an AMX compound may be of any suitable size. The particles comprising an AMX compound are typically nanoparticles comprising an AMX compound. The particles comprising an AMX compound typically have a particle size of from 5 to 100 nm. For instance, the particles may have a particle size of from 7 to 80 nm, for instance from 8 to 40 nm.

The stated particle sizes relate to individual crystals of comprising the AMX compound and not to aggregates of such crystals.

The particle size of the particles may be as measured by electron microscopy. For instance, at least 50% of the particles may have a maximum dimension of from 5 to 100 nm as measured by microscopy (for instance aided by computer image analysis). The particle size may alternatively be an average particle size, for instance a Dv50 (median particle size by volume) as measured by laser diffraction. The particles comprising an AMX compound may further comprise a dispersant. The dispersant may be any suitable dispersant. The dispersant may be a compound comprising a phosphate group, a phosphonic acid group, a carboxylate group or an amino group. For instance, the dispersant may be a compound comprising a phosphate group or a phosphonic acid group. The particles comprising an AMX compound may comprise a dispersant which is polyoxyethylene (10) ether phosphate or octylphosphonic acid.

The particles comprising an AMX compound typically further comprise a ligand. The ligand is typically resent at the surface of the particles comprising an AMX compound. The ligands may for instance be chemically bound to ions at the surface of the particles comprising an AMX compound.

The ligand may be a compound comprising an amine group, a compound comprising an ammonium group, a compound comprising a carboxylic acid group, a compound comprising a sulfonate group, a compound comprising a phosphonate group, a compound comprising a phosphate group or a compound comprising a thiol group. For instance, the ligand may be a compound of formula RNH₂ or RCOOH, where R is a saturated or unsaturated C₄₋₂₀ hydrocarbon radical, for instance where R is C₄₋₂₀ alkyl or C₄₋₂₀ alkylene. The ligand may for instance be oleylamine or oleic acid. The ligand may be a zwitterionic compound. For instance, the ligand may be a compound comprising an ammonium group and a sulfonate group. The ligand may be 3-(N,N-dimethyloctadecylammonio)propanesulfonate.

The photoresist layer in step (a) comprises a mixture of the photoresist and the particles comprising an AMX compound. The photoresist layer may comprise from 5 to 60 wt % of the particles comprising the AMX compound relative to the total weight to the photoresist layer. The photoresist layer may comprise from 5 to 25 wt % of the particles comprising the AMX compound relative to the total weight to the photoresist layer, for instance from 8 to 12 wt % or from 15 to 25 wt %.

The process may further comprise producing the photoresist layer disposed on a substrate by: (i) milling a mixture comprising the particles of an AMX material, a dispersant and a solvent to obtain a slurry; (ii) mixing the slurry with the photoresist to obtain a mixture of a photoresist and particles comprising an AMX compound; and (iii) disposing the mixture of a photoresist and particles comprising an AMX compound on the substrate to produce the photoresist layer. The amount of photoresist mixed with the slurry is typically from 0.5 to 10 g of photoresist per g of slurry.

The particles, dispersant and solvent may for instance be milled using a ball mill. The dispersant may be any suitable dispersant, for instance polyoxyethylene (10) ether phosphate or octylphosphonic acid. The solvent is typically a non-polar solvent, for instance benzene, toluene or xylene. The solvent may be a glycol ether solvent, for instance propylene glycol methyl ether acetate (PGMEA). The photoresist and slurry may be mixed in a planetary mixer to obtain the mixture of a photoresist and particles comprising an AMX compound.

The mixture of a photoresist and particles may be deposited on a substrate by any suitable means to form the photoresist layer. For instance, the mixture may be deposited by blade coating, spin-coating, slit coating or slot-die coating. After depositing the mixture on the substrate, the mixture may be heated to remove the solvent present in the mixture. The process may accordingly further comprise a step (a1) between steps (a) and (b), wherein step (a1) comprises heating the photoresist layer. Heating the photoresist layer may comprise heating the photoresist layer at a temperature of from 40° C. to 100° C., for instance from 60° C. to 80° C. The photoresist layer may be heated for a time of from 1 to 100 minutes, for instance from 5 to 20 minutes.

The process may also comprise a heating step once the patterned photoresist layer has been treated with the developer. This step may be referred to as a hard bake step. The process may accordingly further comprise a step (d) after step (c) and wherein step (d) comprises heating the patterned film comprising particles comprising an AMX compound at a temperature of from 100°° C. to 250° C. The patterned film may for instance be heated at a temperature of from 100° C. to 150° C. or at a temperature of from 180° C. to 220° C. The patterned film may be heated for a time of from 1 to 100 minutes, for instance from 10 to 40 minutes.

Also provided by the invention is a patterned film obtainable by a process according to the invention.

### Processes for Producing a Colour Conversion Layer or a Device

The invention also provides a process for producing a patterned colour conversion layer, the process comprising carrying out a process of the invention to produce one or more patterned films comprising particles comprising an AMX compound. For instance, the process may comprise producing a first patterned film comprising particles comprising an AMX compound that emits green light and subsequently producing a second patterned film comprising particles comprising an AMX compound that emits red light. The AMX compound that emits green light may for instance be (H₂N═C(H)—NH₂)PbBr₃. The AMX compound that emits red light may for instance be CsPb(I_{0.6}Br_{0.4})₃.

A patterned colour conversion layer typically comprises (a) an array of regions of a first matrix material, which first matrix material has particles comprising a first AMX compound dispersed therein and (b) an array of regions of a second matrix material, which second matrix material has particles comprising a second AMX compound dispersed therein. The patterned colour conversion layer may further comprise (c) an array of regions of a third matrix material, which third matrix material has particles comprising a third AMX compound dispersed therein.

The process may for instance comprise: (1) carrying out a process of the invention to produce a first patterned film comprising particles comprising a first AMX compound on a substrate; and (2) carrying out a process of the invention to produce a second patterned film comprising particles comprising a second AMX compound on the substrate, wherein the second AMX compound is different from the first AMX compound.

The invention also provides a process for producing a device comprising a patterned colour conversion layer, the process comprising producing a patterned colour conversion layer by a process according to the invention. The process may for instance comprise (a) producing a patterned colour conversion layer and (b) affixing a light source to the patterned colour conversion layer.

The device produced by the process of the invention is typically a device comprising a display. The display may comprise the colour conversion layer and a light source. The light source may for instance comprise a plurality of light emitting diodes, for instance a plurality of light emitting diodes comprising gallium nitride (GaN). The light source may emit light in the blue range (for instance from 340 nm to 380 nm). The device may be a computer, a laptop, a television, a phone or a tablet.

### Device Intermediate

The invention also provides a device intermediate comprising (i) a patterned photoresist layer disposed on a substrate and (ii) a developer, wherein:

the patterned photoresist layer comprises (a) regions comprising a cured photoresist and particles comprising an AMX compound and (b) regions comprising an uncured photoresist and particles comprising an AMX compound.

The developer typically comprises a solvent, which solvent has a dielectric constant of at least 6.0.

The AMX compound typically comprises a compound of Formula (I):

[A]ₐ[M]_{b}[X]_{c} (I)

wherein: [A] comprises one or more monocations; [M] comprises one or more metal or metalloid cations; [X] comprises one or more halide anions; a is from 1 to 8; b is from 1 to 4; and c is from 3 to 10.

The device intermediate typically comprises (i) the patterned photoresist layer disposed on a substrate and, disposed on the patterned photoresist layer, (ii) the developer. As such, the device intermediate is an article which is formed during the process of the invention during treatment of the patterned photoresist layer with the developer.

The cured photoresist and the uncured photoresist are each typically derived from the same photoresist, with whether the photoresist is cured or uncured dependent on whether the photoresist has been exposed to light. For instance, the patterned photoresist layer may comprise (a) a first plurality of regions comprising a photoresist and particles comprising an AMX compound and (b) a second plurality of regions comprising a photoresist and particles comprising an AMX compound, wherein the first plurality of regions have been exposed to a greater dose of UV light than the second plurality of regions. The cured regions are typically the regions which are not removed from the substrate when the patterned photoresist layer is treated with the developer.

The invention also provides a process for producing a patterned film comprising particles comprising an AMX compound, which process comprises treating a patterned photoresist layer with a developer to produce the patterned film comprising particles comprising an AMX compound, wherein:

the patterned photoresist layer comprises (a) regions comprising a cured photoresist and particles comprising an AMX compound and (b) regions comprising an uncured photoresist and particles comprising an AMX compound.

The developer typically comprises a solvent, which solvent has a dielectric constant of at least 6.0.

The AMX compound typically comprises a compound of Formula (I):

[A]ₐ[M]_{b}[X]_{c} (I)

wherein: [A] comprises one or more monocations; [M] comprises one or more metal or metalloid cations; [X] comprises one or more halide anions; a is from 1 to 8; b is from 1 to 4; and c is from 3 to 10.

### Photoresist Mixture

Also provided by the invention is a photoresist mixture comprising a mixture of a photoresist and particles comprising an AMX compound. The photoresist and particles comprising an AMX compound may be as defined above. The particles comprising an AMX compound may be “green” perovskite nanoparticles comprising formamidinium lead tribromide ((H₂N—C(H)═NH₂)PbBr3) or “red” perovskite nanoparticles comprising cesium lead iodide bromide (CsPb(lo.6Bro.4)3).

Typically, the photoresist mixture comprises:
(a) a binder comprising an acrylate binder or a polyisoprene binder;
(b) a photoinitiator; and
(b) particles comprising a perovskite compound which is CsPb(I_{0.6}Br_{0.4})₃ or (H₂N—C(H)═NH₂)PbBr₃,
wherein the photoresist mixture comprises from 5 to 40 wt % of the particles relative to the total weight of the photoresist mixture.

The photoresist mixture may comprise:
(a) a polyisoprene binder;
(b) a photoinitiator;
(c) particles comprising a perovskite compound which is (H₂N—C(H)═NH₂)PbBr₃; and
(d) a dispersant, which dispersant is optionally polyoxyethylene (10) ether phosphate,
wherein the photoresist mixture comprises from 15 to 20 wt % of the particles relative to the total weight of the photoresist mixture.

The photoresist mixture may comprise:
(a) a polyisoprene binder;
(b) a photoinitiator;
(c) particles comprising a perovskite compound which is CsPb(I_{0.6}Br_{0.4})_{3;} and
(d) a dispersant, which dispersant is optionally octylphosphonic acid,
wherein the photoresist mixture comprises from 5 to 10 wt % of the particles relative to the total weight of the photoresist mixture.

The photoresist mixture may comprise:
(a) an acrylate binder and a diacrylate compound, optionally wherein the diacrylate compound is glycerol 1,3-diglycerolate diacrylate;
(b) a photoinitiator, optionally wherein the photoinitiator comprises 2-hydroxy-2-methylpropiophenone, phenyl bis(2,4,6-trimethylbenzoyl)-phosphine oxide and ethyl phenyl(2,4,6-trimethylbenzoyl)phosphinate;
(c) particles comprising a perovskite compound which is (H₂N—C(H)═NH₂)PbBr₃ or CsPb(I_{0.6}Br_{0.4})_{3;} and
(d) a dispersant, which dispersant is optionally polyoxyethylene (10) ether phosphate,
wherein the photoresist mixture comprises from 5 to 40 wt % of the particles relative to the total weight of the photoresist mixture.

The invention will be described in more detail by the following examples, which are provided for illustrative purposes.

### EXAMPLES

### Example 1

Fabrication of Green FAPbBr₃ Nanocrystals (“Green Nanocrystals”) 0.333 g (3.2mmol) of Formamidine acetate salt (FAAc: Aldrich 99%) was dissolved into 1 mL of HBr (Aldrich: 48 wt. % in H₂O, ≥99.99%) and the solution was mixed by a vortex mixer until obtaining a clear solution. 1.174 g (3.2 mmol) of PbBr₂ (Aldrich ≥98%) was dissolved into 2 mL of HBr (Aldrich: 48 wt. % in H₂O, >99.99%) and the solution was mixed with magnetic stir bar at room temperature (20° C.).

The aqueous FAAc solution was slowly added into the PbBr₂ solution whilst stirring with magnetic stir bar at 18-20° C. At a certain point, an orange precipitate appeared in the solution. 10 mL of acetone (Aldrich: ACS reagent, ≥99.5%) was added into the solution holding the precipitate and mixed with a vortex mixer for 10-20 seconds. The precipitate was taken out on PTFE Depth Filter (pore size 2 μm: Advantec) and washed with ethanol a few times. It was dried in a vacuum oven at 70° C. for 10 h.

500 mg of dried FAPbBr₃ powder and 500 mg of ligands (3-(N,N-Dimethyloctadecylammonio)propanesulfonate: SB3-18) were milled in a planetary ball mill for 3 hour (ZrO₂ beads, 0.3 mm) with 5 mL toluene.

Fabrication of CsPb(I_{0.6}Br_{0.4})₃ Nanocrystals (“Red Nanocrystals”) 0.121 g (0.6 mmol) of Phenethylammonium bromide, 0.779 g (0.3 mmol) of CsI, 0.221 g (0.48 mmol) of PbI₂, 0.044 g (0.12 mmol) of PbBr₂ and 50 mg of (3-(N,N-Dimethyloctadecylammonio)propanesulfonate: SB3-18) were dissolved in 1 mL N,N- Dimethylformamide (DMF: anhydrous, 99.8%). The perovskite precursor solution was injected into 10 mL of chlorobenzene. The perovskite crystals were immediately formed after addition of 1 mL precursor.

10 mL methyl acetate was added into the perovskite dispersion, and it was centrifuged at 7500 rpm for 5 min to collect the precipitate. The precipitate was washed with 10 mL methyl acetate/toluene mixed solvent (1:1 vol.) twice, then the perovskite dispersion was obtained by redispersing in neat toluene.

Photoresist formulation

The green nanocrystals were first redispersed in toluene. The nanocrystals were then separated by centrifugation and the supernatant discarded. A dispersant (Hypermer KD24, Croda; polyoxyethylene (10) ether phosphate; anionic dispersant, 100% active content; 200 mg per gram of perovskite) and toluene (1 mL per g of perovskite) was added to the pellet, and milled in a planetary ball mill for 1 hour (ZrO₂ beads, 3 mm). The slurry was mixed with a polyisoprene photoresist base containing a photoinitiator (Aldrich, 65 179-6, 2.5 g per g of slurry, used without dilution) in a planetary mixer to remove bubbles. The photoresist final formulation contains 18 wt % of green perovskite.

For the red perovskite photoresist, the same procedure was applied, with a different dispersant (octylphosphonic acid, 25 mg per g of perovskite) and a different amount of photoresist base (Aldrich, 65 179-6, 5 g per g of slurry). The photoresist final formulation contains 9 wt % of red perovskite.

### Patterning Process

The perovskite photoresist was coated onto a glass substrate by blade coating in an inactinic light environment. The films were dried at 70° C. for 10 min. Then the films were exposed to UV light through a mask using an LED i-line UV curing chamber (Hoenle, LED cube) with a dose of about 1200 mJ/cm². After exposure, the samples were developed in a xylene-based developer (Aldrich, 65 178-8; xylene (70-90%) and 2-methoxyethyl acetate (20-30%)) and baked at 120° C. for 30 min.

### Characterisation

The films were imaged with a digital microscope using UV LED illumination (˜390-400 nm) fitted with an emission cut-off filter at a wavelength of 425 nm. The resolution of the pattern is under 40 μm (limited by the exposure lamp). No residual photoresist is visible in the images (FIG. 1)

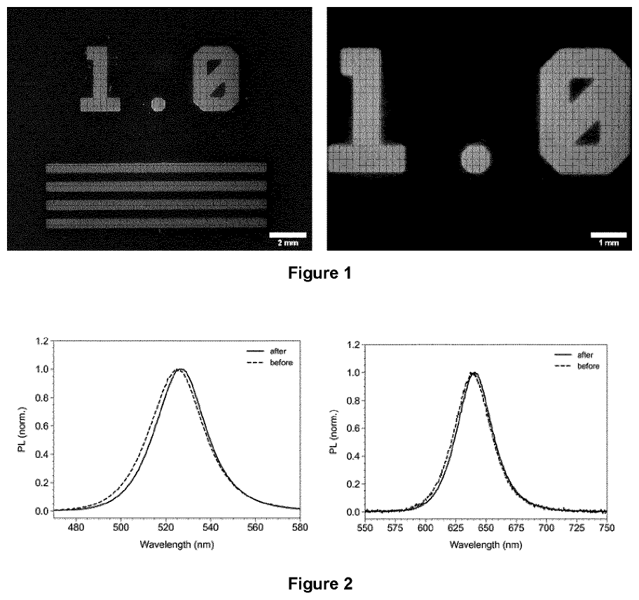

Photoluminescence spectra and photoluminescence quantum yields (PLQY) were measured with a calibrated integrated sphere using a fibre-coupled spectrometer (MayaPro, Ocean Optics) and a 450 nm laser diode for excitation (CPS450, Thorlabs). In FIG. 2, the PL spectra of the films before (i.e. following UV curing) and after the development and baking steps are shown. Minor changes of the peak positions are observed before and after the development and baking process.

The peak positions and photoluminescence quantum yields are summarised in Table 1. The high residual PLQY indicates that the perovskites undergo minor degradation during the process. Interestingly, the PLQY is higher after processing. This could be due to a higher light extraction efficiency following an increase in the sidewall area after patterning. More waveguided light can escape if the sidewall area is increased.

### Example 2

The green and red nanocrystals were synthesised as described in Example 1.

Photoresist Formulation 1 g of green nanocrystals were first redispersed in toluene. The nanocrystals were then separated by centrifugation and the supernatant discarded. A dispersant (Hypermer KD24, Croda; polyoxyethylene (10) ether phosphate; anionic dispersant, 100% active content; 200 mg per gram of perovskite), and toluene (1 mL per g of perovskite) was added to the pellet and milled in a planetary ball mill for 1 hour (ZrO₂ beads, 3 mm). The slurry was mixed with an acrylate binder (BYK-LPX23017, a solution of a copolymer with acidic groups in a solvent mixture comprising 2-methoxy-1-methylethyl acetate, 1.25 g per gram of slurry), a photoinitiator (Omnirad 2022, IGM; mixture of 2-hydroxy-2-methylpropiophenone (60-80%), Phenyl bis(2,4,6-trimethylbenzoyl)-phosphine oxide (10-25%) and Ethyl phenyl(2,4,6-trimethylbenzoyl)phosphinate (5-10%), 0.05 g per g of slurry) and an acrylate monomer (Glycerol 1,3-diglycerolate diacrylate, Sigma-Aldrich, 1.25 g per g of slurry) in a planetary mixer to remove bubbles.

### Patterning Process

The perovskite photoresist was coated onto a glass substrate by blade coating in an inactinic light environment. The films were dried at 80° C. for 10 min. Then the films were exposed to UV light through a mask using an LED i-line UV curing chamber (Hoenle, LED cube) with a dose of about 6000 mJ/cm². After exposure, the samples were developed in an aqueous-based developer (0.05% KOH) and baked at 120° C. for 30 min.

### Characterisation

In FIG. 3, an optical micrograph of a green perovskite patterned film is shown. As for Example 1, no residual photoresist is observed in the non-exposed regions after development.

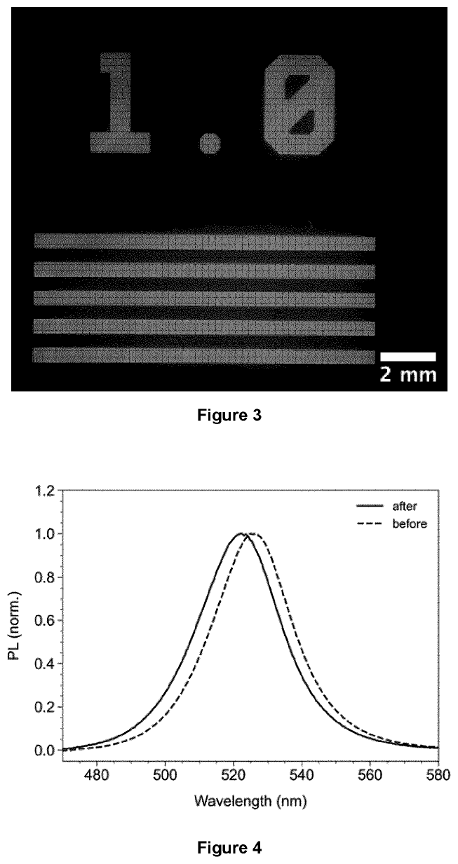

In FIG. 4, the PL spectra of the films before (i.e. following UV curing) and after the development and baking steps are shown. After completion of the process the peak is slightly blue shifted, which can be due to the reduction of the thickness of the film during the development process. This is consistent with the observed increase in PLQY after development (Table 1), since a thinner film would be less subject to reabsorption of the emitted light. The high PLQY maintain throughout the whole process confirms that the perovskite nanocrystals are not degraded.

### Example 3

The red nanocrystals were synthesised as described in Example 1.

Photoresist Formulation 1 g of red nanocrystals were first redispersed in propylene glycol methyl ether acetate (PGMEA). The nanocrystals were then separated by centrifugation and the supernatant discarded. PGMEA (1 mL per g of perovskite) and a small amount of a surfactant was added to the pellet and milled in a planetary ball mill for 1 hour (ZrO₂ beads, 3 mm). The slurry was mixed with an acrylate binder (Mixture of 40 wt % hexa-functional aliphatic urethane acrylate (PHOTOMER 6628), 40 wt % TRIMETHYLOLPROPANE [3 EO] TRIACRYLATE (PHOTOMER 4149), 20 wt % Neopentyl glycol diacrylate (Photomer® 4127), 1 g per gram of slurry), a photoinitiator (Omnirad 2022, IGM; mixture of 2-hydroxy-2-methylpropiophenone (60-80%), Phenyl bis(2,4,6-trimethylbenzoyl)-phosphine oxide (10-25%) and Ethyl phenyl(2,4,6-trimethylbenzoyl)phosphinate (5-10%), 0.16 g per g of slurry) and an acrylate monomer (Glycerol 1,3-diglycerolate diacrylate, Sigma-Aldrich, 0.2 g per g of slurry) in a planetary mixer to remove bubbles.

### Patterning Process

The perovskite photoresist was coated onto a glass substrate by blade coating in an inactinic light environment. The films were dried at 80° C. for 1 min. Then the films were exposed to UV light through a mask using an LED i-line UV curing chamber (Hoenle, LED cube) with a dose of about 20.4 J/cm². After exposure, the samples were developed in an aqueous-based developer (0.5 wt % TMAH) for 5 sec and rinsed with deioinised water and IPA:Acetone (1:1 vol ratio). The patterned film was dried with an air gun.

### Characterisation

The peak positions and photoluminescence quantum yields are summarised in Table 1.

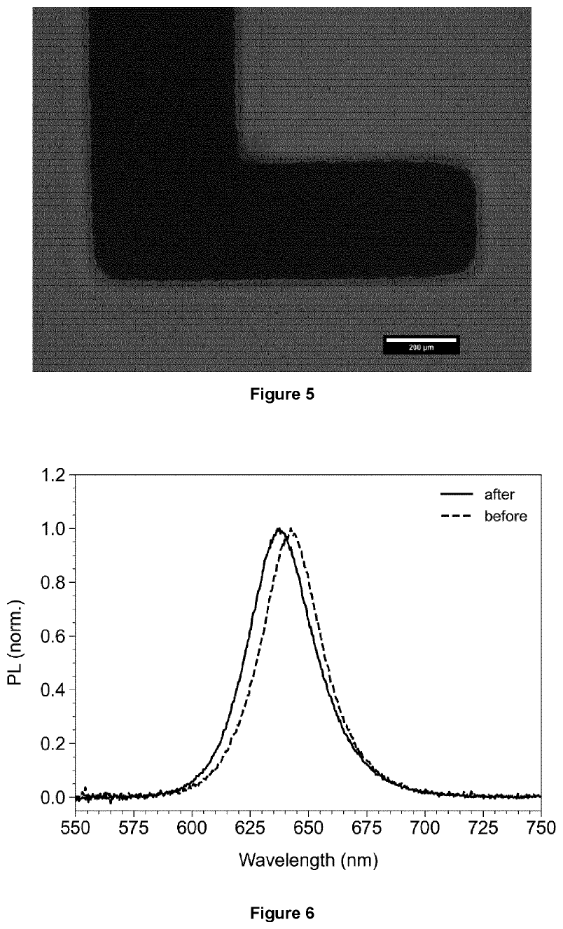

In FIG. 5, an optical micrograph of a red perovskite patterned film is shown. As for Example 1 and 2, no residual photoresist is observed in the non-exposed regions after development.

In FIG. 6, the PL spectra of the films after UV curing and development is shown. The high PLQY is maintained throughout the whole process confirming that the perovskite nanocrystals are not degraded.

TABLE 1
Photoluminescence properties of the patterned perovskite
films before and after the development and baking steps.
(WL: wavelength, PLQY: photoluminescence quantum yield).

| | After UV exposure | | After development and baking | |
|---|---|---|---|---|
| | Peak WL [nm] | PLQY [%] | Peak WL [nm] | PLQY [%] |
| Example 1 | | | | |
| Green | 526 | 22 | 525 | 45 |
| Red | 639 | 5 | 640 | 9 |
| Example 2 | | | | |
| Green | 526 | 71 | 522 | 84 |
| Example 3 | | | | |
| Red | 643 | 55 | 638 | 56 |

1. A process for producing a patterned film comprising particles comprising an AMX compound, which process comprises:
(a) providing a photoresist layer disposed on a substrate, which photoresist layer comprises a mixture of a photoresist and particles comprising an AMX compound;
(b) defining a pattern on the photoresist layer by exposing regions of the photoresist layer to light and thereby producing a patterned photoresist layer; and
(c) treating the patterned photoresist layer with a developer to produce the patterned film comprising particles comprising an AMX compound,
wherein:
the developer comprises a solvent, which solvent has a dielectric constant of at least 6.0; and
the AMX compound comprises a compound of Formula (I):
[A]ₐ[M]_{b}[X]_{c} (I)
wherein: [A] comprises one or more monocations; [M] comprises one or more metal or metalloid cations; [X] comprises one or more halide anions; a is from 1 to 8; b is from 1 to 4; and c is from 3 to 10.

2. A process according to claim 1, wherein the developer comprises water, an alcohol solvent, an ester solvent or a ketone solvent,
preferably wherein the developer comprises water.

3. A process according to claim 1 or claim 2, wherein the developer is an aqueous solution comprising a hydroxide compound.

4. A process according to any one of the preceding claims, wherein defining a pattern on the photoresist layer by exposing regions of the photoresist layer to light comprises exposing the photoresist layer to UV light through a patterned mask.

5. A process according to any one of the preceding claims, wherein exposing regions of the photoresist layer to light comprises exposing regions of the photoresist layer to UV light at a dose of at least 40 mJ/cm², preferably at a dose of from 500 to 10,000 mJ/cm².

6. A process according to any one of the preceding claims, wherein the photoresist is a photopolymerising resist, a photocrosslinking resist or a photodecomposing resist,
preferably wherein the photoresist is a photopolymerising resist or a photocrosslinking resist.

7. A process according to any one of the preceding claims, wherein the photoresist comprises a binder, a photoinitiator and optionally a monomer.

8. A process according to claim 7, wherein the binder comprises an acrylate binder, a methacrylate binder, an alkene binder, a vinyl binder or an epoxy binder,
preferably wherein the binder is a polymer or an oligomer,
more preferably wherein the binder comprises an isoprene polymer, an acrylate polymer or a methacrylate polymer.

9. A process according to claim 7 or claim 8, wherein the photoresist further comprises a cross-linking agent and the cross-linking agent comprises a compound comprising two or more acrylate groups, two or more methacrylate groups, two or more alkene groups, or two or more epoxide groups,
preferably wherein the cross-linking agent is a compound comprising two acrylate groups or a compound comprising two methacrylate groups,
more preferably wherein the cross-linking agent is glycerol 1,3-diglycerolate diacrylate.

10. A process according to any one of claims 7 to 9, wherein the photoinitiator comprises a compound comprising a ketone group, a benzoyl group, an azide group, a phosphine oxide group, a phosphinate group, an oxime group or a ketal group,
preferably wherein the photoinitiator comprises a compound comprising a benzoyl group, a phosphine oxide group or a phosphinate group,
more preferably wherein the photoinitiator comprises 2-hydroxy-2-methyl-1-phenylpropanone, bis(2,4,6-trimethylbenzoyl)phenylphosphine oxide and ethyl(2,4,6-trimethylbenzoyl)-phenyl phosphinate.

11. A process according to any one of the preceding claims, wherein the AMX compound comprises a compound of Formula (II):
[A][M][X]₃ (II)
wherein:
[A] comprises one or more monocations, optionally wherein [A] comprises one or more organic monocations;
[M] comprises one or more metal or metalloid dications; and
[X] comprises one or more halide anions.

12. A process according to any one of the preceding claims, wherein:
[A] comprises one or more cations selected from (CH₃NH₃)⁺, (H₂N—C(H)═NH₂)⁺ and Cs⁺;
[M] comprises one or more metals or metalloid dications selected from Pb²⁺, Sn²⁺, Cu²⁺ and Ge2+; and
[X] comprises one or more of Cl⁻, Br⁻ and I⁻.

13. A process according to any one of the preceding claims, wherein the particles comprising an AMX compound have a particle size of from 5 to 100 nm.

14. A process according to any one of the preceding claims, wherein the particles comprising an AMX compound further comprise a dispersant,
preferably wherein the dispersant is compound comprising a phosphate group or a phosphonic acid group.

15. A process according to any one of the preceding claims, wherein the particles comprising an AMX compound further comprise one or more ligands,
preferably wherein the ligand is a compound comprising an amine group, a compound comprising an ammonium group, a compound comprising a carboxylic acid group, a compound comprising a sulfonate group, or a compound comprising a thiol group.

16. A process according to any one of the preceding claims, wherein the photoresist layer in step (a) comprises from 5 to 60 wt % of the particles comprising the AMX compound relative to the total weight to the photoresist layer.

17. A process according to any one of the preceding claims, wherein the process further comprises producing the photoresist layer disposed on a substrate by:
(i) milling a mixture comprising the particles of an AMX compound, a dispersant and a solvent to obtain a slurry;
(ii) mixing the slurry with the photoresist to obtain a mixture of a photoresist and particles comprising an AMX compound; and
(iii) disposing the mixture of a photoresist and particles comprising an AMX compound on the substrate to produce the photoresist layer.

18. A process according to any one of the preceding claims, wherein the process further comprises a step (a1) between steps (a) and (b) and wherein step (a1) comprises heating the photoresist layer,
preferably wherein heating the photoresist layer comprises heating the photoresist layer at a temperature of from 40° C. to 100° C., optionally for a time of from 1 to 100 minutes.

19. A process according to any one of the preceding claims, wherein the process further comprises a step (d) after step (c) and wherein step (d) comprises heating the patterned film comprising particles comprising an AMX compound at a temperature of from 100° C. to 250° C., optionally for a time of from 1 to 100 minutes.

20. A process according to any one of the preceding claims, wherein the pattern defined on the photoresist layer is an array of pixels.

21. A process for producing a patterned colour conversion layer, the process comprising carrying out a process as defined in any one of the preceding claims to produce one or more patterned films comprising particles comprising an AMX compound.

22. A process according to claim 21, which process comprises:
(1) carrying out a process as defined in any one of the preceding claims to produce a first patterned film comprising particles comprising a first AMX compound on a substrate; and
(2) carrying out a process as defined in any one of the preceding claims to produce a second patterned film comprising particles comprising a second AMX compound on the substrate,
wherein the second AMX compound is different from the first AMX compound.

23. A process for producing a device comprising a patterned colour conversion layer, the process comprising producing a patterned colour conversion layer by a process as defined in claim 21 or claim 22.

24. A device intermediate comprising (i) a patterned photoresist layer disposed on a substrate and (ii) a developer,
wherein:
the patterned photoresist layer comprises (a) regions comprising a cured photoresist and particles comprising an AMX compound and (b) regions comprising an uncured photoresist and particles comprising an AMX compound;
the developer comprises a solvent, which solvent has a dielectric constant of at least 6.0; and
the AMX compound comprises a compound of Formula (I):
[A]ₐ[M]_{b}[X]_{c} (I)
wherein: [A] comprises one or more monocations; [M] comprises one or more metal or metalloid cations; [X] comprises one or more halide anions;
a is from 1 to 8; b is from 1 to 4; and c is from 3 to 10.

25. A photoresist mixture which comprises:
(a) a binder comprising an acrylate binder or a polyisoprene binder;
(b) a photoinitiator; and
(b) particles comprising a perovskite compound which is CsPb(I_{0.6}Br_{0.4})₃ or (H₂N—C(H)═NH₂)PbBr₃,
wherein the photoresist mixture comprises from 5 to 40 wt % of the particles comprising a perovskite compound relative to the total weight of the photoresist mixture.
